(19) United States
(12) Patent Application Publication
(10) Pub. No.: US 2007/0278674 A1
(43) Pub. Date: Dec. 6, 2007

(54) POWER SEMICONDUCTOR ARRANGEMENT WITH SOLDERED CLIP CONNECTION AND METHOD

(75) Inventor: Oliver Haeberlen, Villach (AT)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Muenchen (DE)

(21) Appl. No.: 11/757,039

(22) Filed: Jun. 1, 2007

(30) Foreign Application Priority Data
Jun. 2, 2006 (DE) 10 2006 025 959.9

(51) Int. Cl. H01L 23/48

(52) U.S. Cl. 257/737

(57) ABSTRACT

A power semiconductor arrangement with soldered clip connection and a method for producing such an arrangement is disclosed. One embodiment provides a semiconductor chip with soldered clip connection. A solderable front-side power metallization layer is provided. A gate finger structure is provided. A structured passivation layer is provided for the insulation of the gate finger from the soldered clip connection, the solderable power metallization layer being arranged over the passivation layer.

### CROSS-REFERENCE TO RELATED APPLICATIONS

This Utility Patent Application claims priority to German Patent Application No. DE 10 2006 025 959.9 filed on Jun. 2, 2006, which is incorporated herein by reference.

### BACKGROUND

The invention relates to a power semiconductor arrangement and to a method for producing such an arrangement.

In the course of the development of semiconductor technology, innumerable arrangements and methods have been developed for the external contacting of the actual semiconductor elements or circuits, including the known wire bonding and die bonding methods that are used in practice in a wide variety of different forms.

Especially in the field of power semiconductor arrangements, increasing power requirements have in recent years led to the establishment of new mounting techniques. This has been particularly in pursuit of the aim of reducing the ohmic resistance and inductance of the external connections. This aim of providing lower-resistance and lower-inductance chip connections is served by replacing the conventional wire bonding connections on the front side of the chip with soldered clip connections. Since the conventional front-side Al-based metallizations cannot be soldered or at least cannot be readily soldered, this fundamental change in the connecting technology requires that the conventional metallization for the source terminal or power metallization is replaced with an intrinsically solderable power metallization or requires the application of a solderable power metallization on a base metallization of the known Al-based type.

For the connection of the gate voltage in semiconductor arrangements—especially also power semiconductors—with high requirements for the switching speed, it is known to provide a finger structure of the gate terminals for a transistor cell array, which is also referred to as “gate fingers” for short. If semiconductor arrangements with such a gate finger structure are to be externally connected to soldered clip connections in the way under discussion here, the gate fingers must of course be insulated from the soldered clip, which is at source potential. For this purpose, it is known to use a passivation layer over the gate fingers, usually one which is based on silicon nitride (Si₃N₄), silicon oxide (SiO₂) or a polymer, in particular an imide. Such a passivation layer is usually applied after the formation of the structured solderable power metallization layer.

In the case of this technique, it has been found to be disadvantageous that the passivation layer is not wetted by the solder when the clip is soldered on for the external connection of the chip. Since, in every soldering method, wetting with a flux takes place before the solder is applied, there is the real risk of flux residues remaining on the passivation layer. As already demonstrated in practice, these chemically aggressive flux residues can lead to a time-dependent deterioration of properties of the power semiconductor arrangement, known as degradation.

There are also known techniques by which use of the preferred chip connection is realized by a soldered clip connection and, nevertheless, the disadvantageous effects of flux residues remaining on a passivation layer can be prevented. For instance, it is known to configure the soldered-on clip geometrically in adaptation to the existing gate finger structure in such a way that there are no regions of a passivation layer that are covered by the clip.

It is also known to protect certain regions of a previously produced thick silicon oxide passivation layer against the action of flux residues by using currentless or electroless deposition of an additional metallization layer. Furthermore, it has become known in the case of certain power semiconductor structures of the FET type, known as DirectFET, to subject the solderable front side of the chip to a common structuring with a base alloy metallization and subsequently cover the gate fingers with a material similar to a molding compound.

However, all the approaches mentioned have proven to be disadvantageous from certain aspects. In particular, the functionally more convincing solutions among these make the method more complicated and therefore also lead to increased costs of the semiconductor arrangements created.

For these and other reasons, there is a need for the present invention.

One or more embodiments provide an improved method for producing such an arrangement which reliably preclude any problems of reliability, in particular when solderable clip connections are used, without making production much more complicated, and consequently without leading to higher production costs.

As a fundamental reversal of the previous method sequence, one or more embodiments include forming a solderable power metallization layer after application of a passivation layer to insulate the gate fingers. This has the consequence that the ready-passivated gate fingers are provided in the region of the clip connection, as well as in the other regions of the surface, with a layer which can be wetted by the solder.

All the surface regions of the front side of the chip, or all the regions between this front side of the chip and the corresponding surface of the clip, can be completely filled with solder, so there are no longer any regions in which flux residues can remain. One further advantage is the more uniform connection of the regions of the transistor cell arrays that are electrically separated by the gate finger structure in the chip.

In one embodiment of the power semiconductor arrangement, it is provided that the solderable power metallization layer covers the passivation layer substantially completely.

In one embodiment, the solderable power metallization layer has a multilayer structure, an upper layer that is adjacent a solder for the clip connection including Ag or an Ag alloy. Here, the thickness of the upper layer is in particular 100 to 700 nm, with particular preference between 150 and 500 nm. With such a thickness, a reasonable compromise is achieved between reliable solder wettability of the metallization layer and a comparatively small layer thickness.

In a further embodiment, it is provided that the solderable power metallization layer has a three-layer structure with a lower Ti or Ti-alloy layer, a middle Ni or Ni-alloy layer and an upper Ag or Ag-alloy layer. This layer structure is configured particularly expediently with a layer thickness of the solderable power metallization layer in the range between 450 and 1750 nm, with preference between 550 and 850 nm and with particular preference of 700 nm.

The layer thicknesses of the individual component layers are chosen as follows: the layer thickness of the lower Ti or Ti-alloy layer lies in the range between 150 and 450 nm, with preference at 300 nm, the thickness of the middle Ni or Ni-alloy layer lies between 100 and 600 nm, with preference between 200 and 400 nm, and the thickness of the upper Ag or Ag-alloy layer lies between 100 and 700 nm, with preference between 150 and 500 nm.

The solderable power metallization layer under discussion here is provided as an additional layer on an AlSi, AlCu or AlSiCu base metallization. However, as an alternative to this, one that is well within the scope of the invention, a different base metallization may also serve as the basis.

In a further embodiment, it is provided that the solderable power metallization layer is arranged on a passivation layer which has a thin SiN or SiO₂ adhesion layer passivation with a thickness in the range between 20 and 100 nm, with preference between 30 and 70 nm, and an imide layer with a thickness in the range between 3 and 10 μm, with preference between 5 and 7 μm. There are also alternatives to this; for instance, silicon oxides and/or nitrides deposited in a plasma-assisted manner may serve alone as the passivation.

The features and embodiments of the proposed power semiconductor arrangement that have been mentioned above have equivalent features of a corresponding production method, so there is no need here for them to be repeated in detail. However, it should be pointed out that in one embodiment the method according to the invention includes the following processes: forming and structuring a passivation layer in a configuration suitable for the insulation of an existing gate finger structure from a source potential that is present at a clip connection soldered later and depositing and structuring a solderable power metallization layer over the base metallization layer and the structured passivation layer in a configuration suitable for producing the solderable clip connection.

Here, the structuring of the passivation layer in particular includes etching, in particular plasma etching, of the Si₃N₄ or SiO₂ adhesion layer, with masking provided by the imide layer photochemically structured in advance.

In another embodiment, the depositing of the solderable power metallization layer takes the form of a vacuum deposition or sputtering process, and this is in particular a multistep process, in the final stage of which, that is to say as a solder-wettable surface of the metallization, an Ag or Ag-alloy layer is deposited with sufficient thickness (as mentioned above).

In another embodiment, it is provided that, before the depositing of the solderable power metallization layer, a photoresist layer is applied and structured and, after the depositing of the solderable power metallization layer, structuring of the same is performed by a liftoff process.

Since the proposed solution is suitable in particular for power semiconductor arrangements in the form of thin semiconductor chips, with a thickness of 250 μm or less, in particular 175 μm or less, the proposed method can be completed by a process of thinning the back side of the wafer after the aforementioned process steps. It goes without saying that this thinning can also be followed—in a way known per se—by the back-side implantation and/or metallization of the wafer.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic representation of an exemplary embodiment, as a cross-sectional representation of a power metallization layer sequence of a power semiconductor arrangement.

FIGS. 2A to 2D illustrate schematic cross-sectional representations for explaining a production method according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

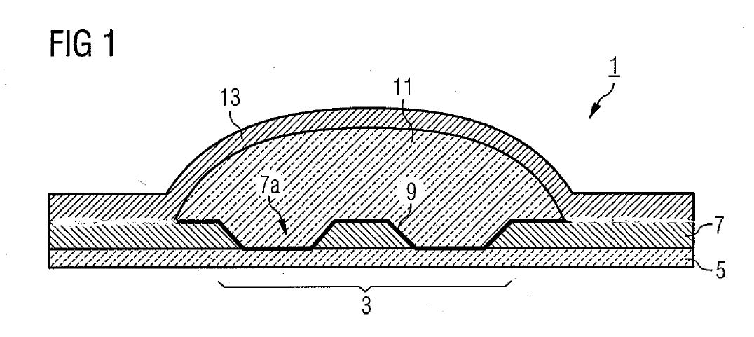

FIG. 1 illustrates a layer structure 1 according to one embodiment of a power metallization over a gate finger region 3 of a power FET (not represented here as a whole). Represented as the lowermost layer is an insulating layer 5, which is also referred to as the intermediate oxide (ZWOX), as it is typically provided on a gate electrode of the power FET consisting of poly Si (not represented here). This layer generally includes boron- and/or phosphor-doped silicate glass (abbreviated designations BSG, PSG and BPSG, respectively). Applied on top is an AlSiCu solder layer 7, which is structured in a predetermined way and in which two exposed regions 7a are illustrated in the figure. Provided on this is a silicon nitride layer (abbreviated designation SNIT) 9, deposited in a plasma-assisted manner.

In one embodiment, applied over the structured region of the solder layer 7 that is covered with SNIT is a relatively thick imide layer 11, the adhesion of which on the solder layer 7 is improved by the SNIT layer 9. Over the solder layer 7 and (where provided) the imide layer 11 there finally extends a power metallization (LVS) layer 13. By the provision of the imide layer 11 in the gate finger region 3 underneath the power metallization 13, the gate fingers are electrically insulated from the latter in a reliable and comparatively uncomplicated way.

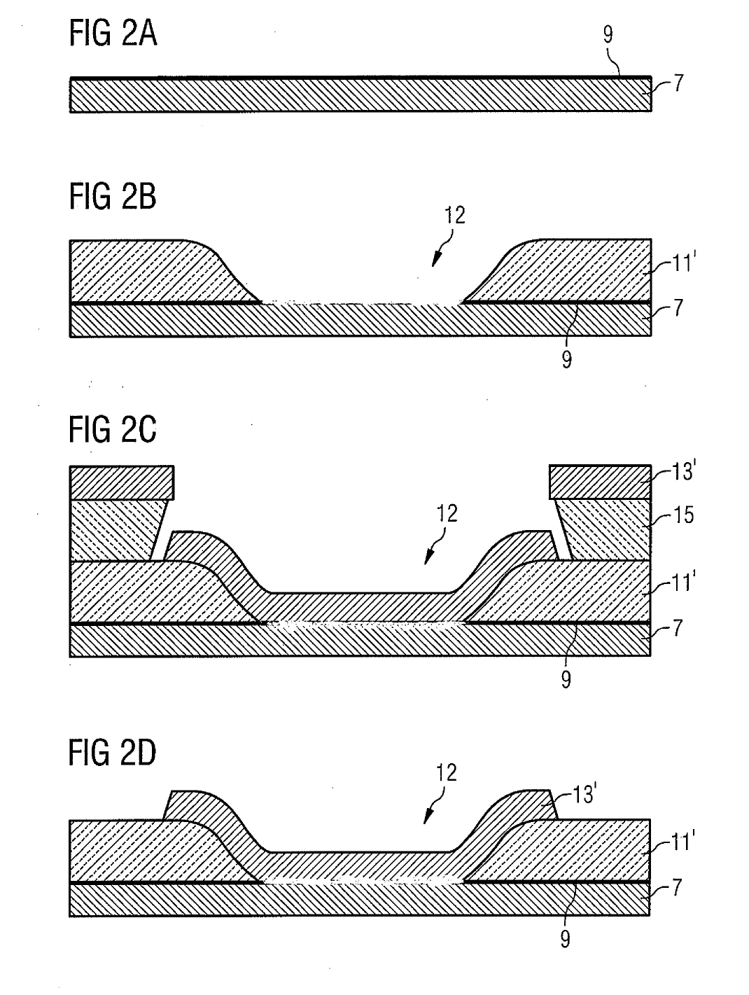

The production of this layer structure is explained in somewhat more detail on the basis of FIGS. 2A to 2D, in which however, by contrast with FIG. 1, the intermediate oxide layer 5 has been omitted and the AlSiCu solder layer 7 as such is illustrated unstructured. Here, FIG. 2A illustrates as an (arbitrarily assumed) starting point simply an unstructured AlSiCu solder layer 7, which in practice is for example 3.2 μm thick, as a base metallization with a sputtered-on, 40 nm thick protective nitride passivation, which also acts as an adhesion promoter for the following layer.

FIG. 2B illustrates the layer structure with this following layer, to be specific a 6 μm thick imide layer 11′ that can be structured by photolithography, known as a photoimide. An opening 12 has been formed in this and in the protective nitride layer 9 by suitable etching processes.

For this purpose, the photoimide, which is photosensitive after application, is first structured by using a lithography process and is subsequently crosslinked for mechanical stabilization. Since the protective nitride layer 9 lying under the imide layer 11′ is etched with the structured imide layer 11′ as a mask, the crosslinking of the latter is performed in two stages: first, what is known as a “hard bake” is performed at 200° C., whereby the solvent content of the imide layer is drastically reduced, in order to prevent contamination of the vacuum chamber with solvent vapors in a subsequent plasma etching of the protective nitride layer.

After the hard bake, a brief ° 2 plasma etching is performed, by which any organic deposits on the exposed region of the opening 12 are intended to be removed. After this brief plasma etching, the actual complete crosslinking of the imide layer is performed, also referred to as cyclization. This process typically lasts for one to two hours and is performed as a thermal treatment in the range between 380° C. and 420° C. in an inert gas atmosphere. This is followed by repeated brief etching in oxygen plasma, in order once again to remove any organic deposits that may have formed from the metallic surfaces during the cyclization.

Next, using suitable masking methods for a subsequent liftoff, as it is known, a photoresist layer, also correspondingly referred to as photo liftoff 15, is applied to the imide layer 11′ outside the region of the opening 12 in such a way that the edge of the resist has a negative edge angle or “overhang” near the region of the opening 12. After the mentioned structuring of this intermediate layer 15, the power metallization 13′ is deposited over the entire surface area, both onto the portions that are covered with resist and onto the portions that are free from resist.

This is a three-layer structure including a Ti layer, in the example 300 nm thick, a 200 nm thick NiV layer deposited over it and a 200 nm thick Ag layer applied over that, likewise by sputtering. (The layer structure is not represented in the figures.) The way in which the method is conducted, with the corresponding vacuum coating processes, is conventional.

The entire construction is subjected to a liftoff process, which as such has long been known and in which the photoresist layer 15 together with the metallization layer 13′ deposited on it is removed from the wafer surface by a combination of chemical and mechanical action (solvent/pressure jet). The power metallization resting on the AlSiCu metal layer in the region of the opening 12 has such great adhesion there that it is not removed, and also not damaged, in this process. The state that is illustrated in FIG. 2D is then reached.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor arrangement having a semiconductor chip comprising:
a soldered clip connection;
a power metallization layer; and
a gate finger structure; and
a structured passivation layer configured to insulate the gate finger structure from the soldered clip connection, were the solderable power metallization layer is arranged over the passivation layer.

2. The arrangement of claim 1, comprising wherein the solderable power metallization layer substantially completely covers the passivation layer in a region of the gate finger.

3. The arrangement of claim 1, comprising wherein the solderable power metallization layer has a multilayer structure, wherein an upper layer that is adjacent a solder for the clip connection comprises a high-grade metal.

4. The arrangement of claim 3, the solderable power metallization layer has a three-layer structure comprising a lower Ti or Ti-alloy layer, a middle Ni or Ni-alloy layer and an upper Ag or Ag-alloy layer.

5. The arrangement of claim 1, comprising wherein the solderable power metallization layer is arranged on an AlSi, AlCu or AlSiCu base metallization.

6. The arrangement of claim 1, comprising wherein the solderable power metallization layer is arranged on a passivation layer, having an adhesion layer passivation and an imide layer.

7. The arrangement of in claim 1, comprising wherein the soldered clip connection and the power metallization layer belonging are provided above a die bonding connection and the power semiconductor arrangement with the die bonding connection and the clip connection is enclosed in a plastic package.

8. A power semiconductor arrangement comprising:
where the power semiconductor arrangement is configured as a FET including a thin semiconductor chip with a substrate thickness of 250 μm or less further comprising:
a front-side soldered clip connection to a external terminal;
a solderable front-side power metallization layer configured for a source terminal;
a gate finger structure configured for a gate terminal;
a structured passivation layer configured for the insulation of the gate fingers from the soldered clip connection at source potential; and
wherein the solderable power metallization layer is arranged over the passivation layer.

9. The arrangement of claim 8, comprising wherein the solderable power metallization layer covers the passivation layer in the region of the gate finger substantially completely.

10. The arrangement of claim 8, comprising wherein the solderable power metallization layer has a multilayer structure, wherein an upper layer that is adjacent a solder for the clip connection comprising a high-grade metal including Ag or an Ag alloy.

11. The arrangement of claim 10, comprising wherein the thickness of the upper layer is between 150 and 500 nm.

12. The arrangement of claim 10, comprising wherein the solderable power metallization layer has a three-layer structure with a lower Ti or Ti-alloy layer, a middle Ni or Ni-alloy layer and an upper Ag or Ag-alloy layer.

13. The arrangement of claim 8, comprising wherein a layer thickness of the solderable power metallization layer is in the range between 450 and 1750 nm, with preference between 550 and 850 nm.

14. The arrangement of claim 12, comprising wherein a layer thickness of the lower Ti or Ti-alloy layer is in the range between 150 and 450 nm, a thickness of the middle Ni or Ni-alloy layer is between 100 and 600 nm, and a thickness of the upper Ag or Ag-alloy layer is between 100 and 700 nm.

15. The arrangement of claim 8, comprising wherein the solderable power metallization layer is arranged on an AlSi, AlCu or AlSiCu base metallization.

16. The arrangement of claim 8, comprising wherein the solderable power metallization layer is arranged on a passivation layer, which has a thin Si3N4 or SiO2 adhesion layer passivation with a thickness in the range between 20 and 100 nm, and an imide layer with a thickness in the range between 3 and 10 μm.

17. The arrangement of in claim 8, comprising wherein the soldered clip connection and the power metallization layer belonging to the latter are provided above a die bonding connection and the power semiconductor arrangement with the die bonding connection and the clip connection is enclosed in a plastic package.

18. A method for manufacturing a power semiconductor arrangement of the FET type comprising:
depositing and structuring a base metallization layer;
forming and structuring a passivation layer in a configuration suitable for insulation of an existing gate finger structure from a source potential present at a clip connection soldered later; and
depositing and structuring a solderable power metallization layer over the base metallization layer and the structured passivation layer in a configuration suitable for producing the solderable clip connection.

19. The method of claim 18 comprising:
defining the base metallization layer to comprise AlSi, AlCu or AlSiCu.

20. The method of claim 18, comprising wherein the depositing of the passivation layer comprises the formation of an Si3N4 or SiO2 adhesion layer with a thickness in the range between 20 and 100 nm, and the application of an imide layer with a thickness in the range between 3 and 10 μm.

21. The method of claim 18, comprising wherein the structuring of the passivation layer comprises plasma etching, of the Si3N4 or SiO2 adhesion layer, with masking provided by the imide layer photochemically structured in advance.

22. The method of claim 18, comprising carrying out the depositing of the solderable power metallization layer out as a vacuum deposition or sputtering process.

23. The method of claim 18, comprising wherein the depositing of the solderable power metallization layer is a multistep process, in the final stage of which an Ag or Ag-alloy layer is deposited with a layer thickness between 100 and 700 nm.

24. The method of claim 18, comprising wherein, before the depositing of the solderable power metallization layer, a photoresist layer is applied and structured and, after the depositing of the solderable power metallization layer, structuring of the solderable power metallization layer is performed by a liftoff process.

25. The method of claim 18, comprising a process of grinding down the back side to form a thin semiconductor chip with a thickness of 250 μm or less.
